(19) United States
(12) Patent Application Publication
(10) Pub. No.: US 2023/0042359 A1
(43) Pub. Date: Feb. 9, 2023

(54) ELECTROMAGNETIC WAVE SHIELDING COMPOSITION

(71) Applicant: NAMICS CORPORATION, Niigata-Shi, Niigata (JP)

(72) Inventors: Takashi YONEDA, Niigata-shi, Niigata (JP); Yoshitaka KAMATA, Niigata-Shi, Niigata (JP); Noriyuki SAKAI, Niigata-shi, Niigata (JP); Hironobu TSUBURA, Niigata-Shi, Niigata (JP); Satomi KAWAMOTO, Niigata-Shi, Niigata (JP); Yoshito YAMADA, Niigata-Shi, Niigata (JP)

(73) Assignee: NAMICS CORPORATION, Niigata-Shi, Niigata (JP)

(21) Appl. No.: 17/786,282

(22) PCT Filed: Dec. 4, 2020
(86) PCT No.: PCT/JP2020/045154

§ 371 Date: Jun. 16, 2022

(30) Foreign Application Priority Data
Dec. 23, 2019 (JP) 2019-232012

(51) Int. Cl. H01B 1/22; H05K 9/00

(52) U.S. Cl. CPC H01B 1/22; H05K 9/0083

(57) ABSTRACT

An electromagnetic shielding composition includes silver particles (A), and a first solvent (B). The first solvent (B) has at least one structure selected from the group consisting of a structure represented by the formula (1) and a structure represented by the formula (2) and has a boiling point of less than 200° C.

### TECHNICAL FIELD

The present invention relates to an electromagnetic shielding composition for forming an electromagnetic shielding layer on an electronic component or the like that is mounted on a substrate.

### BACKGROUND ART

Electronic components such as a power amplifier, a. Wi-Fi/Bluetooth module, and a flash memory are mounted on substrates built in electronic devices such as a mobile phone, a smartphone, a notebook computer, and a tablet terminal. Such electronic components may malfunction due to external electromagnetic waves. Conversely, the electronic components may be sources of electromagnetic noise, which may cause malfunction of other electronic components.

In the field of electronic devices, development of a high integration technology for integrating a plurality of components into one component, such as a system-on-chip (SoC), a system-in-package (SiP), and a multi-chip module (MCM), has progressed, and the electronic devices have been increasingly reduced in size and thickness. As the electronic devices become smaller and thinner, there is an increasing need to protect components such as baseband components, radio frequency (RF) components, wireless components, analog devices, and power management components from electromagnetic interference (hereinafter, also referred to as “EMI”).

In an electronic component, a shielding layer made of a metal plate for blocking electromagnetic waves is formed, or a three-layer shielding layer in which a stainless steel (SUS) layer/copper (Cu) layer/stainless steel (SUS) layer are stacked from the inside is formed, for example, on an outer surface of the electronic component by sputtering.

It is difficult for the shielding layer made of the metal plate to satisfy requirements for reduction in size and thickness of an electronic device. In the shielding layer formed by sputtering, the thickness of a shielding layer formed on the top (upper surface) of the electronic component is different from that of a shielding layer formed on the side (side surface) of the electronic component. Attempting to make the thicknesses of the shielding layers formed on the top (upper surface) and the side (side surface) uniform, may take a long time for sputtering and increase cost.

The shielding layer can be formed not only by sputtering but also by spray-coating a surface of the electronic component. For example, Patent Literature 1 discloses an EMI shielding composition for forming a shielding layer on a surface of an electronic component by spray coating. The EMI shielding composition disclosed in Patent Literature 1 contains (a) a thermoplastic resin such as a phenoxy resin or a vinylidene resin and/or a thermoset resin such as an epoxy resin or an acrylic resin. (b) a solvent or a reactive diluent such as 2-phenoxyethyl acrylate, and (c) conductive particles such as silver particles. Patent Literature 1 describes that the EMI shielding composition encapsulates a functional module disposed on a substrate using a spray coating machine or a dispensing, jetting machine.

### CITATION LIST

### Patent Literature

Patent Literature 1: JP-A-2017-520903

### SUMMARY OF INVENTION

### Technical Problem

The shielding layer is required to further enhance an EMI shielding effect.

An object of one embodiment of the present invention is to provide an electromagnetic shielding composition that can further enhance an EMI shielding effect

### Solution to Problem

A solution to the problem is as follows, and the present invention includes the following aspects.

A first aspect of the present invention is directed to an electromagnetic shielding composition including: silver particles (A); and a first solvent (B) that has at least one structure selected from the group consisting of a structure represented by the following formula (1) and a structure represented by the following formula (2) and has a boiling point of less than 200″C.

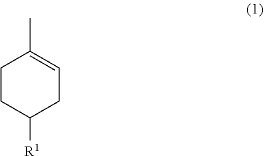

(In the formula (1), R¹ is an alkyl group having 2 to 3 carbon atoms and having a double bond between the carbon atoms.)

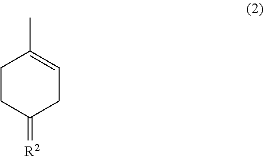

(In the formula (2), R² is an alkylidene group having 2 to 3 carbon atoms.)

A second aspect of the present invention is directed to an electronic component using the electromagnetic shielding composition.

### Advantageous Effects of Invention

In the present invention, it is possible to provide an electromagnetic shielding composition that can reduce the specific resistance and further enhance an EMI shielding effect.

### DESCRIPTION OF EMBODIMENTS

Hereinafter, an electromagnetic shielding composition in the present disclosure is described based on embodiments. However, the following embodiments are examples for embodying a technical thought of the present invention, and the present invention is not limited to the following electromagnetic shielding composition.

An electromagnetic shielding composition in a first embodiment of the present invention includes: silver particles (A); and a first solvent (B) that has at least one structure selected from the group consisting of a structure represented by the following formula (1) and a structure represented by the following formula (2) and has a boiling point of less than 200° C.

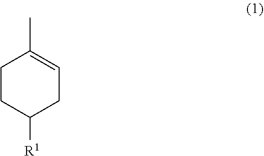

In the formula (1), R¹ is an alkyl group having 2 to 3 carbon atoms and having a double bond between the carbon atoms. In the formula (1), specific examples of the R¹ include a vinyl group, a 1-propenyl group, a 2-propenyl group (allyl group), and an isopropenyl group. Among these, the R¹ is preferably the isopropenyl group.

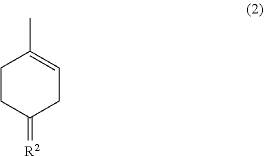

In the formula (2), R² is an alkylidene group having 2 to 3 carbon atoms. The R² in the formula (2) represents an alkylidene group including a double bond in the formula (2). In the formula (2), specific examples of the R², as the alkylidene group including the double bond in the formula (2), include an ethylidene group, a propylidene group, and an isopropylidene group. Among these, the isopropylidene group is preferable.

Since the electromagnetic shielding composition in the first embodiment of the present invention contains the first solvent (B) that has at least one structure selected from the structure represented by the formula (1) and the structure represented by the formula (2) and has a boiling point of less than 200° C., the electromagnetic shielding composition has high volatility, a specific resistance of a shielding layer formed from the electromagnetic shielding composition is low and an EMI shielding effect can be enhanced. The first solvent (B) may be a solvent having the structure represented by the formula (1) or a solvent having the structure represented by the formula (2), as long as the boiling point of the first solvent (B less than 200° C. The first solvent (B) may contain both the solvent having the structure represented by the formula (1) and the solvent having the structure represented by the formula (2), and both may have the boiling point of less than 200° C.

A shielding effect of the shielding layer against EMI is expressed by reflection loss (dB). The reflection loss can be calculated by the following calculation formula (I). In the following calculation formula (I), K is represented by the following calculation formula (II), and is a ratio of impedance of a space to impedance of the shielding layer. As the specific resistance of the shielding layer decreases, that is, as conductivity increases, the impedance of the shielding layer decreases, the ratio of the impedance of the space to the impedance of the shielding layer also decreases, the reflection loss (dB) increases, and the EMI shielding effect of the shielding layer can be enhanced. The shielding layer obtained from the electromagnetic shielding composition in the first embodiment of the present invention has a low specific resistance and can enhance the EMI shielding effect.

$$R = 20 log \frac{{\vert 1 + K \vert}^{2}}{4 \vert K \vert} \qquad ( I )$$

In the calculation formula (I), R represents the reflection loss (dB), and K represents the ratio of the impedance of the space to the impedance of the shielding layer, as shown in the following calculation formula. (II).

$$K = \frac{{Z}_{S}}{{Z}_{0}} \qquad ( II )$$

In the calculation formula (II), Z₀ represents the impedance of the space, and Z_{S} represents the impedance of the shielding layer.

Silver Particles (A)

In the electromagnetic shielding composition, the silver particles (A) are blended as conductive particles to shield electromagnetic waves. An average particle diameter of the silver particles (A) is preferably in a range of 30 nm or more and 350 nm or less, more preferably in a range of 40 nm or more and 300 run or less, and still more preferably in a range of 50 nm or more and 250 nm or less. In the case where the average particle diameter of the silver particles (A) is in the range of 30 nm or more and 350 nm or less, precipitation of the silver particles in the electromagnetic shielding composition can be prevented, a dispersion state of the silver particles in the composition can be maintained, and a shielding layer having an enhanced EMI shielding effect can be easily formed.

The average particle diameter of the silver particles can be measured by, for example, observation using a scanning electron microscope (hereinafter, also referred to as “SEM”). For example, the average particle diameter is obtained by acquiring SEM photographs or SEM images of the silver particles at magnifications of 10,000 times to 20,000 times, approximating contours of the silver particles present in the SEM photographs or the SEM images to perfect circles, measuring diameters of the perfect circles, and taking an arithmetic average value of diameters of any 50 silver particles as the average particle diameter.

A shape of the silver particles may be any shape such as a spherical shape, a scale-like shape, or a needle-like shape. In the case where the shape of the silver particles is the scale-like shape or the needle-like shape, an average value of scale-like or needle-like silver particles on a long axis can be taken as the average particle diameter. From a viewpoint of preventing precipitation in the electromagnetic shielding composition, the silver particles (A) are preferably spherical.

Specifically, as the silver particles, silver powder (product name: P620-7. P620-24) manufactured by Metalor Technologies USA, and silver powder (product name: Ag nano powder-2) manufactured by DOWA Electronics Materials Co., Ltd. can be used.

The silver particles (A) are preferably contained in the electromagnetic shielding composition in a range of 35% by mass or more and 95% by mass or less, and may be contained in a range of 40% by mass or more and 90% by mass or less in terms of solid content.

A master batch in which the silver particles (A) are dispersed in the first solvent (B) and/or a second solvent (D) other than the first solvent (B) may be used. The master batch is one in a slurry form prepared by dispersing the silver particles in advance in the first solvent (B) and/or the second solvent (D). In the case where the master batch containing the silver particles (A) is used in the electromagnetic shielding composition, the silver particles (A) are less likely to precipitate in the electromagnetic shielding composition, and a state in which the silver particles are appropriately dispersed in the composition is easily maintained.

As the first solvent (B) and/or the second solvent (D) that is a solvent other than the first solvent (B) contained in the master hatch, one kind of a solvent may be used, or two or more kinds of solvents may be used. The master batch may contain both the first solvent (B) and the second solvent (D) that is a solvent other than the first solvent (B). As the second solvent (D) that is a solvent other than the first solvent (B), for example, at least one selected from the group consisting of ethylene glycol monophenyl ether (EPH), butyl carbitol acetate (BCA), and butyl carbitol (BC) can be used. As the first solvent (B) or the second solvent (D), one kind of a solvent may be used, or two or more kinds of solvents may be used in combination. An amount of the first solvent (B) or the second solvent (D) contained in the master batch may be any amount as long as the precipitation of the silver particles (A) contained in the master batch can be prevented and a slurry form can be maintained.

First Solvent (B)

In the electromagnetic shielding composition, the first solvent (B) is preferably limonene or terpinolene. In the case where the first solvent (B) is limonene or terpinolene, the volatility is high, the specific resistance of the shielding layer formed from the electromagnetic shielding composition is low, and the EMI shielding effect can be enhanced.

The limonene is represented by the following formula (3), has a structure represented by the formula (1), and has a boiling point of 176° C.

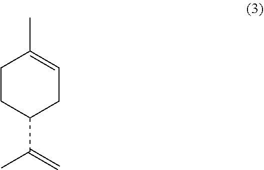

The terpinolene is represented by the following formula (4), has a structure represented by the formula (2), and has a boiling point of 184° C.

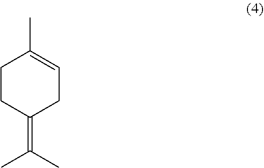

The first solvent (B) is preferably contained in the electromagnetic shielding composition in a range of 5 parts by mass or more and 150 parts by mass or less with respect to 100 parts by mass of the silver particles (A). In the case where the first solvent (B) is contained in the electromagnetic shielding composition in the range of 5 parts by mass or more and 150 parts by mass or less with respect to 100 parts by mass of the silver particles (A), the shielding layer can be formed in a state in which the silver particles (A) are substantially uniformly dispersed, and since the first solvent (B) volatilizes, the shielding layer having a high EMI shielding effect can be formed. An amount of the first solvent (B) contained in the electromagnetic shielding composition is preferably in a range of 6 parts by mass or more and 140 parts by mass or less, and more preferably in a range of 7 parts by mass or more and 130 parts by mass or less with respect to 100 parts by mass of the silver particles (A).

Dispersant (C)

The electromagnetic shielding composition preferably further contains a dispersant (C). By including the dispersant (C) in the electromagnetic shielding composition, dispersibility of the silver particles (A) can be improved, precipitation can be prevented, and the shielding layer having the high EMI shielding effect can be formed.

In the electromagnetic shielding composition, from a standpoint of achieving high compatibility with the first solvent (B) or the second solvent (D), the dispersant (C) is preferably at least one selected from the group consisting of acrylic acid-based dispersants, phosphoric acid ester salt-based dispersants, and polyfunctional ionic dispersants. As the dispersant (C), a carboxylic acid-based dispersant may be used. Examples of the acrylic acid-based dispersant include polyisobutyl methacrylate, Examples of the phosphoric acid ester salt-based dispersant include BYK-145 manufactured by BYK-Chemie GmbH. Examples of the polyfunctional ionic dispersant include MALIALIM (registered trademark) series and SC1015F of MALIALIM (registered trademark) SC series manufactured by NOF Corporation. A dispersant of MALIALIM (registered trademark) series manufactured by NOF Corporation is a polyfunctional comb-shaped dispersant having an ionic group in a main chain and a polyoxyalkylene chain in a graft chain. Examples of the carboxylic acid-based dispersant include a dicarboxylic acid-based weak anionic dispersant (product name: Hypermer KD-57) manufactured by CRODA. Examples of the phosphoric acid ester salt-based dispersant also include a phosphoric acid ester-based dispersant (product name: CRODAFOS O3A) manufactured by CRODA.

The dispersant (C) is preferably contained in the electromagnetic shielding composition in a range of 0.5 parts by mass or more and 10 parts by mass or less with respect to 100 parts by mass of the silver particles (A). In the case where the dispersant (C) is contained in the electromagnetic shielding composition in the range of 0.5 parts by mass or more and 10 parts by mass or less with respect to 100 parts by mass of the silver particles (A), the precipitation of the silver particles (A) can be prevented and the shielding layer can be formed in the state in which the silver particles are substantially uniformly dispersed, and a shielding layer having a low specific resistance and a high EMI shielding effect can be formed. An amount of the dispersant (C) contained in the electromagnetic shielding composition is preferably in a range of 1 part by mass or more and 8 parts by mass or less, and more preferably in a range of 1.5 parts by mass or more and 7 parts by mass or less, with respect to 100 parts by mass of the silver particles (A).

The dispersant (C) may be contained in the master batch prepared by dispersing the silver particles (A) in a slurry form in advance. In the case where the dispersant (C) is contained in the master batch, the precipitation of the silver particles (A) can be prevented and the shielding layer can be formed in the state in which the silver particles are substantially uniformly dispersed, and the shielding layer having the high EMI shielding effect can be formed. Even when the dispersant (C) is contained in the master batch, the dispersant (C) may be contained in the range of 0,5 parts by mass or more and 10 parts by mass or less with respect to 100 parts by mass of the silver particles (A) contained in the electromagnetic shielding composition.

The electromagnetic shielding composition may contain an additive, Examples the additive include a silane coupling agent and a defoaming agent. The additive may be added to the electromagnetic shielding composition, and may be added to the master batch in the case where the master batch is used. An amount of the additive in the electromagnetic shielding composition is preferably in a range of 0.01 parts by mass or more and 5 parts by mass or less, and preferably in a range of 0.05 parts by mass or more and 3 parts by mass or less, with respect to 100 parts by mass of the electromagnetic shielding composition. Even when the additive is added to the master batch, the amount of the additive in the electromagnetic shielding composition to which the master batch has been added may be in the range of 0.01 parts by mass or more and 5 parts by mass or less with respect to 100 parts by mass of the electromagnetic shielding composition.

The silane coupling agent can be blended to increase heat resistance and adhesive strength of the electromagnetic shielding composition. For example, various same coupling agents such as epoxy-based silane coupling agents, amino-based silane coupling agents, vinyl-based silane coupling agents, methacrylic silane coupling agents, acrylic silane coupling agents, and mercapto-based silane coupling agents can be used. Among these, the epoxy-based silane coupling agent having an epoxy group and the methacrylic silane coupling agent having a methacrylic group are preferable. Specifically, an epoxy-based silane coupling agent (3-glycidoxypropyltrimethoxysilane) (product name: KBM403) manufactured by Shin-Etsu Chemical Co., Ltd., a methacrylic silane coupling agent (3-methacryloxypropyltrimethoxysilane) (product name: KBM503) manufactured by Shin-Etsu Chemical Co., Ltd., and the like can be used.

The defoaming agent is blended to prevent generation of bubbles in the electromagnetic shielding composition, and for example, acrylic defoaming agents, silicone-based defoaming agents, and fluorosilicone-based defoaming agents can be used. Specifically, a silicone-based defoaming agent (product name: WACKER AF98/1000) manufactured by Wacker Asahikasei Silicone Co., Ltd. or the like can be used. In the case where the silane coupling agent is added, the silane coupling agent can be added in a range of 0.001 parts by mass or more and 5 parts by mass or less with respect to 100 parts by mass of the silver particles (A).

Viscosity

A viscosity of the electromagnetic shielding composition is preferably in a range of 10 mPa·s or more and 10,000 mPa·s or less, more preferably in a range of 20 mPa·s or more and 2,000 mPa·s or less, and still more preferably in a range of 30 mPa·s or more and 1,000 mPa·s or less, as measured at 25° C. and a rotational speed of 10 rpm using, for example, a rotational viscometer (product number: TVE-22H) manufactured by Tokyo Keiki Inc. In the case where the viscosity of the electromagnetic shielding composition measured at 25° C. and 10 rpm is in the range of 10 mPa·s or more and 10,000 mPa·s or less, the silver particles (A) are dispersed in the electromagnetic shielding composition, and the shielding layer having the high EMI shielding effect can be formed by spray coating (spraying).

Thixotropic index Ti (5 rpm/50 rpm)

A thixotropic index Ti of the electromagnetic shielding composition is preferably in a range of 1 or more and 6 or less, and more preferably in a range of 1.2 or more and 5.0 or less. The thixotropic index is a ratio of a viscosity measured at a rotational speed of 5 rpm at 25° C. to a viscosity measured at a rotational speed of 50 rpm at 25° C. using, for example, the rotational viscometer (product number: TVE-22H) manufactured by Tokyo Keiki mc. The thixotropic index Ti is an index for measuring dependence of a shear rate (rotational speed of a viscometer) and a viscosity and indicating thixotropy. A Ti value of a Newtonian fluid such as water whose viscosity does not change even when a shear rate changes is 1. In a case where the Ti value is smaller than 1, the smaller a shear force is, the smaller the viscosity is as compared with the case where the shear force is large, and in a case where the Ti value is larger than 1, the smaller the shear force is, the larger the viscosity is as compared with the case where the shear force is large. The larger the Ti value is, the more thixotropy is exhibited. In the case where the Ti value of the electromagnetic shielding composition is in the range of 1 or more and 6 or less, the shielding layer having the high EMI shielding effect can be formed by the spray coating (spraying).

Method for Producing Electromagnetic Shielding Composition

The electromagnetic shielding composition can be produced by blending, for example, the silver particles (A), the first solvent (B), the dispersant (C) as necessary, and the additive as necessary, and stirring and mixing the components using a common device. As the common device, for example, a Henschel mixer, a roll mill, a three-roll mill, or the like can be used. The silver particles (A), the first solvent (B), the dispersant (C) as necessary may be simultaneously added to the device and mixed, or a part thereof may be first added to the device and mixed, and the rest thereof may be subsequently added to the device and mixed.

Method for Producing Master Batch

The master batch in a slurry form can be produced by stirring and mixing the silver particles (A) and the first solvent (B) and/or the second solvent (D) that is a solvent other than the first solvent (B) in advance. The master batch may contain the dispersant (C), and may contain the additive as necessary. The silver particles (A) and the first solvent (B) and/or the second solvent (D) contained in the master batch can be stirred and mixed using the common device described above.

Coating Method

The electromagnetic shielding composition can be sprayed on an electronic component or the like to form a shielding layer on an outer surface of the electronic component or the like. The electromagnetic shielding composition can be coated to the electronic component by, for example, a spray coating machine common in the related art. Further, the electromagnetic shielding composition filling an aerosol can or the like may be applied. A thickness of the shielding layer formed by spraying the electromagnetic shielding composition on the electronic component may be in a range of 5 μm or more and 30 μm or less, may be in a range of 5 μm or more and 20 μm or less, or may be in a range of 5 μm or more and 10 μm or less.

Specific Resistance

A specific resistance of the shielding layer formed by spraying the electromagnetic shielding composition may be 30 Ω·cm or less, preferably 25 Ω·cm or less, more preferably 20 Ω·cm or less, still more preferably 10 Ω·cm or less, particularly preferably 7 Ω·cm or less, and may be 1 Ω·cm or more. As the specific resistance of the shielding layer formed by spraying the electromagnetic shielding composition decreases, that is, as the conductivity increases, the impedance of the shielding layer decreases, the ratio of the impedance of the space to the impedance of the shielding layer also decreases, the reflection loss (dB) increases, and the EMI shielding effect of the shielding layer can be enhanced.

The specific resistance can be measured, for example, by a four-terminal method using a multimeter (product number: 2001 type) manufactured by TOYO Corporation for a shielding layer formed by spraying the electromagnetic shielding composition on an alumina substrate in a specific size and length and drying the composition in a hot air dryer at 200° C. for 30 minutes.

Electronic Component

The electromagnetic shielding composition can be applied to an electronic component by spray coating or the like. Examples of the electronic component to which the electromagnetic shielding composition is applied include a power amplifier, a Wi-Fi/Bluetooth module, and a flash memory, which are used in electronic devices such as a mobile phone, a smartphone, a notebook computer, and a tablet terminal. In the case where the electromagnetic shielding composition is used for the electronic component, each electronic component to which the electromagnetic shielding composition has been applied may be mounted on a substrate, or the electromagnetic shielding composition may be applied after each electronic component is mounted on the substrate.

### EXAMPLES

Hereinafter, the present invention is described in detail with reference to examples. The present invention is not limited to these examples.

In producing electromagnetic shielding compositions in Examples and Comparative Examples, the following raw materials were used.

Silver Particles (A)

A1: Spherical, average particle diameter: 100 μm, silver filler, manufactured by Metalor Technologies USA, product number: P620-24

A2: Spherical, average particle diameter 60 nm, silver filler, manufactured by DOWA Electronics Materials Co., Ltd, product number: Ag nano powder-2

A3: Spherical, average particle diameter: 200 inn, silver filler, manufactured by Metalor Technologies USA, product number: P620-7

The average particle diameter of the silver particles (A) was obtained by observing the silver particles (A) using a scanning electron microscope (SEM), selecting any 50 particles from SEM photographs or SEM images at magnifications of 10,000 times to 20,000 times, approximating contours of the particles to perfect circles, measuring diameters of the perfect circles, and taking an arithmetic average value of the diameters as the average particle diameter. In the case where the shape of the silver particles is a flake (scale-like), an average value of any 50 silver particles on a long axis can be taken as the average particle diameter.

Third Solvent (B′)

Unlike a first solvent (B) described later, the third solvent (B′) does not have at least one structure selected from the structure represented by the formula (1) and the structure represented by the formula (2), and has a boiling point of 200° C. or higher. The third solvent (B′) may be the same as or different from the second solvent (D) that is a solvent other than the first solvent (B).

B′1: Butyl carbitol (BC) (90% by mass to 100% by mass of di ethylene glycol monobutyl ether), manufactured by Daishin Chemical Co., Ltd., boiling point 247° C.

B′2: Terpineol, manufactured by Kobayashi Perfumery Co., Ltd., boiling point 219° C.

B′3: Ethylene glycol monobutyl ether, manufactured by Tokyo Chemical Industry Co., Ltd., boiling point 171° C.

First Solvent (B)

The first solvent (B) has at least one structure selected from the group consisting of the structure represented by the formula (1) and the structure represented by the formula (2), and has a boiling point of less than 200° C.

B4: Limonene, manufactured by Nippon Terpene Chemicals Inc., boiling point 176° C.

B5: Terpinolene, manufactured by Nippon Terpene Chemicals Inc., boiling point 184° C.

Dispersant (C)

C1: Polyisobutyl methacrylate, manufactured by Tokyo Chemical Industry Co., Ltd.

C2: Phosphoric acid ester salt-based dispersant, manufactured by BYK-Chemie GmbH, product number: BYK-145

C3: Polyfunctional ionic dispersant, MALIALIM (registered trademark) SC1015F manufactured by NOF Corporation

### Examples 1 to 12 and Comparative Examples 1 to 5

Raw materials were mixed and dispersed using a three-roll mill at blending ratios shown in Tables 1 and 2 below to produce an electromagnetic shielding composition.

### Example 13

An electromagnetic shielding composition was produced in the same manner as in Example 1 except that a master hatch in a slurry form prepared by dispersing the silver filler A1 as the silver particles (A) in the terpinolene as the first solvent (B) in advance was used. The master batch contains 6,0 parts by mass of the first solvent (B) with respect to 100 parts by mass of the silver filler A1 as the silver particles (A). Specifically, an electromagnetic shielding composition was produced in the same manner as in Example 1, except that a blending ratio of the raw materials other than the silver filler, with respect to 100 parts by mass of the silver filler A1 as the silver particles (A) in the master batch, was as shown in Table 2 below.

Viscosity Measurement

A viscosity of each of the electromagnetic shielding compositions in Examples and Comparative Examples was measured at 25° C. at each of rotational speeds of 1 rpm, 5 rpm, 10 rpm, 50 rpm, and 100 rpm using the rotational viscometer (product number: TVE-22H) manufactured by Tokyo Keiki Inc. Results are shown in Tables 1 and 2.

Thixotropic index Ti (5 rpm/50 rpm)

A thixotropic index Ti (5 rpm/50 rpm) of each of the electromagnetic shielding compositions in Examples and Comparative Examples was obtained by acquiring a ratio of a viscosity measured at a rotational speed of 5 rpm at 25° C. to a viscosity measured at a rotational speed of 50 rpm at 25° C. using the rotational viscometer (product number: TVE-22H) manufactured by Tokyo Keiki Inc. Results are shown in Tables 1 and 2.

Specific Resistance

For each of the electromagnetic shielding compositions in Examples and Comparative Examples, two tapes having a thickness of about 85 μm to 95 μm were attached to an alumina substrate in parallel at intervals of 3 mm, the composition was sprayed between the two tapes so as to have a width of 3 mm, a length of 50 mm, and a thickness of about 90 μm, followed by drying in a hot air dryer at 200° C. for 30 minutes to form a shielding layer. The specific resistance of the shielding layer was measured by a four-terminal method using the multimeter (product number: 2001 type) manufactured by TOYO Corporation. Results are shown in Tables 1 and 2.

TABLE 1

| | | | Comparative | Comparative | Comparative | Comparative | Comparative | |
|---|---|---|---|---|---|---|---|---|
| | | | Example 1 | Example 2 | Example 3 | Example 4 | Example 5 | |
| Silver Particles (A) | A1 | Parts by | — | — | 100.00 | 100.00 | 100.00 | |
| | A2 | Mass | 100.00 | 100.00 | — | — | — | |
| | A3 | | — | — | — | — | — | |
| Third Solvent (B′) | B′1 | | 44.16 | — | 12.98 | — | — | |
| | B′2 | | — | 44.16 | — | 12.98 | — | |
| | B′3 | | — | — | — | — | 12.98 | |
| First Solvent (B) | B4 | | — | — | — | — | — | |
| | B5 | | — | — | — | — | — | |
| Dispersant (C) | C1 | | 5.22 | 5.22 | 1.72 | 1.72 | 1.72 | |
| | C2 | | — | — | — | — | — | |
| | C3 | | — | — | — | — | — | |
| Total | | | 149.38 | 149.38 | 114.70 | 114.70 | 114.70 | |
| Master Batch | | | No | No | No | No | No | |
| Specific Resistance | μΩ · cm | | 25.3 | 10.2 | 19.6 | 7.2 | 8.2 | |
| (200° C., 30 min) | | | | | | | | |
| Viscosity (1 rpm) | mPa · s | | 924 | 4667 | 941 | 4075 | 1322 | |
| Viscosity (5 rpm) | mPa · s | | 556 | 2250 | 470 | 2017 | 521 | |
| Viscosity (10 rpm) | mPa · s | | 428 | 1678 | 369 | 1257 | 375 | |
| Viscosity (50 rpm) | mPa · s | | 232 | 924 | 246 | 876 | 201 | |
| Viscosity (100 rpm) | mPa · s | | 183 | 601 | 226 | 578 | 151 | |
| Ti (5 rpm/50 rpm) | | | 2.40 | 2.44 | 1.91 | 2.30 | 2.59 | |
| | | | Example 1 | Example 2 | Example 3 | Example 4 | Example 5 | Example 6 |
| Silver Particles (A) | A1 | Parts by | 100.00 | 100.00 | 100.00 | 100.00 | 100.00 | 100.00 |
| | A2 | Mass | — | — | — | — | — | — |
| | A3 | | — | — | — | — | — | — |
| Third Solvent (B′) | B′1 | | — | — | — | — | — | — |
| | B′2 | | — | — | — | — | — | — |
| | B′3 | | — | — | — | — | — | — |
| First Solvent (B) | B4 | | 12.98 | — | — | — | — | — |
| | B5 | | — | 12.98 | 7.73 | 14.88 | 16.32 | 19.89 |
| Dispersant (C) | C1 | | 1.72 | 1.72 | 1.72 | 1.72 | 1.72 | 1.72 |
| | C2 | | — | — | — | — | — | — |
| | C3 | | — | — | — | — | — | — |

| | | | | | | |
|---|---|---|---|---|---|---|
| Total | 114.70 | 114.70 | 109.45 | 116.60 | 118.04 | 121.61 |

| | | | | | | | |
|---|---|---|---|---|---|---|---|
| Master Batch | | No | No | No | No | No | No |
| Specific Resistance | μΩ · cm | 3.7 | 3.8 | 3.8 | 3.8 | 3.7 | 3.8 |
| (200° C., 30 min) | | | | | | | |
| Viscosity (1 rpm) | mPa · s | 1145 | 1720 | 7350 | 1389 | 203 | 71 |
| Viscosity (5 rpm) | mPa · s | 450 | 737 | 2410 | 557 | 117 | 51 |
| Viscosity (10 rpm) | mPa · s | 317 | 536 | 1463 | 356 | 96 | 46 |
| Viscosity (50 rpm) | mPa · s | 157 | 292 | 605 | 167 | 63.4 | 33 |
| Viscosity (100 rpm) | mPa · s | 122 | 234 | 420 | 128 | 55 | 30 |
| Ti (5 rpm/50 rpm) | | 2.87 | 2.52 | 3.98 | 3.34 | 1.85 | 1.55 |

TABLE 2

| | | | Example 7 | Example 8 | Example 9 | Example 10 | Example 11 | Example 12 | Example 13 |
|---|---|---|---|---|---|---|---|---|---|
| Silver Particles (A) | A1 | Parts by | — | — | 100.00 | 100.00 | 100.00 | 100.00 | 100.00 |
| | A2 | Mass | 100.00 | — | — | — | — | — | — |
| | A3 | | — | 100.00 | — | — | — | — | — |
| Third Solvent (B′) | B′1 | | — | — | — | — | — | — | — |
| | B′2 | | — | — | — | — | — | — | — |
| | B′3 | | — | — | — | — | — | — | — |
| First Solvent (B) | B4 | | — | — | — | — | — | — | — |
| | B5 | | 44.16 | 12.98 | 44.16 | 12.98 | 12.98 | 12.98 | 12.98 |
| Dispersant (C) | C1 | | 5.22 | 1.00 | 0.00 | 5.22 | — | — | 1.72 |
| | C2 | | — | — | — | — | 1.72 | — | — |
| | C3 | | — | — | — | — | — | 1.72 | — |

| | | | | | | | |
|---|---|---|---|---|---|---|---|
| Total | 149.38 | 113.98 | 144.16 | 118.20 | 114.70 | 114.70 | 114.70 |

| | | | | | | | | |
|---|---|---|---|---|---|---|---|---|
| Master Batch | | No | No | No | No | No | No | Yes |
| Specific Resistance | μΩ · cm | 4.9 | 3.6 | 3.5 | 4.4 | 3.8 | 3.8 | 3.7 |
| (200° C., 30 min) | | | | | | | | |
| Viscosity (1 rpm) | mPa · s | 2521 | 421 | 2850 | 695 | 2959 | 1367 | 1702 |
| Viscosity (5 rpm) | mPa · s | 818 | 245 | 990 | 341 | 1370 | 688 | 710 |
| Viscosity (10 rm) | mPa · s | 475 | 203 | 830 | 261 | 979 | 534 | 511 |
| Viscosity (50 rpm) | mPa · s | 167 | 152 | 240 | 164 | 516 | 332 | 285 |
| Viscosity (100 rpm) | mPa · s | 112 | 140 | 133 | 141 | 382 | 280 | 214 |
| Ti (5 rpm/50 rpm) | | 4.90 | 1.61 | 4.13 | 2.08 | 2.66 | 2.07 | 2.49 |

As shown in Tables 1 and 2, each of the shielding layers formed by spraying the electromagnetic shielding compositions in Examples 1 to 13 had a specific resistance of 5 Ω·cm or less. The specific resistance was low that is, the conductivity was high, the impedance of the shielding layer was low, the reflection loss (dB) was high, and the EMI shielding effect was high.

In each of the electromagnetic shielding compositions in Examples 1 to 13, the viscosity measured at 25° C. at each of rotational speeds of 1 rpm, 5 rpm, 10 rpm, 50 rpm, and 100 rpm was in the range of 10 mPa·s or more and 10,000 mPa·s or less, and the silver particles (A) were dispersed in the electromagnetic shielding composition and spray-coating (spraying) could be performed. Each of the electromagnetic shielding compositions in Examples 1 to 13 had thixotropy in which the thixotropic index Ti is in a range of 1 or more and 6 or less and the shielding layer can be formed by spray coating (spraying).

Each of the electromagnetic shielding compositions in Comparative Examples 1 to 5 contains the third solvent (B′), and the third solvent (B′) is a solvent that does not have the structure represented by the formula, (1) or the structure represented by the formula (2) and has the boiling point of 200° C. or higher, and thus is different from the first solvent (B). Each of the shielding layers formed by spraying each of the electromagnetic shielding compositions in Comparative Examples 1 to 5 containing the third solvent (B′) had a higher specific resistance than each of the shielding layers formed by spraying each of the electromagnetic shielding compositions in Examples 1 to 13,

### INDUSTRIAL APPLICABILITY

The electromagnetic shielding composition in the first embodiment of the present invention can form a shielding layer on an electronic component by spray coating, and can be suitably used for electronic components such as a power amplifier, a Wi-Fi/Bluetooth module, and a flash memory, which are used for electronic devices such as a mobile phone, a smartphone, a notebook computer, and a tablet terminal.

1. An electromagnetic shielding composition comprising:
silver particles (A); and
a first solvent (B) that has at least one structure selected from the group consisting of a structure represented by the following formula (1) and a structure represented by the following formula (2) and has a boiling point of less than 200° C., 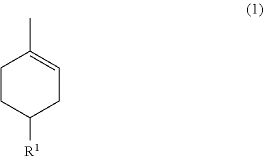
wherein, in the formula (1), R¹ is an alkyl group having 2 to 3 carbon atoms and having a double bond between the carbon atoms, and 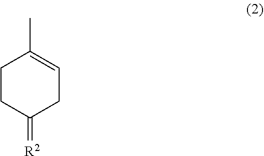
in the formula (2), R² is an alkylidene group having 2 to 3 carbon atoms.

2. The electromagnetic shielding composition according to claim 1, wherein the first solvent (B) is limonene or terpinolene.

3. The electromagnetic shielding composition according to claim 1, further comprising a dispersant (C).

4. The electromagnetic shielding composition according to claim 1, wherein a content of the first solvent (B) is in a range of 5 parts by mass or more and 150 parts by mass or less with respect to 100 parts by mass of the silver particles (A).

5. The electromagnetic shielding composition according to claim 1, wherein the silver particles (A) have an average particle diameter of 30 nm or more and 350 nm or less.

6. The electromagnetic shielding composition according to claim 3, wherein the dispersant (C) is at least one selected from the group consisting of acrylic acid-based dispersants, phosphoric acid ester salt-based dispersants, and polyfunctional ionic dispersants.

7. The electromagnetic shielding composition according to claim 1, which is a master batch in a slurry form in which the silver particles (A) are dispersed in the first solvent (B) and/or a second solvent (D) that is a solvent other than the first solvent (B).

8. The electromagnetic shielding composition according to claim 7, wherein the master batch comprises a dispersant (C).

9. An electronic component comprising a shielding layer formed from the electromagnetic shielding composition according to claim 1.

10. The electromagnetic shielding composition according to claim 2, further comprising a dispersant (C).

11. The electromagnetic shielding composition according to claim 2, wherein a content of the first solvent (B) is in a range of 5 parts by mass or more and 150 parts by mass or less with respect to 100 parts by mass of the silver particles (A).

12. The electromagnetic shielding composition according to claim 3, wherein a content of the first solvent (B) is in a range of 5 parts by mass or more and 150 parts by mass or less with respect to 100 parts by mass of the silver particles (A).

13. The electromagnetic shielding composition according to claim 10, wherein a content of the first solvent (B) is in a range of 5 parts by mass or more and 150 parts by mass or less with respect to 100 parts by mass of the silver particles (A).

14. The electromagnetic shielding composition according to claim 2, wherein the silver particles (A) have an average particle diameter of 30 nm or more and 350 nm or less.

15. The electromagnetic shielding composition according to claim 3, wherein the silver particles (A) have an average particle diameter of 30 nm or more and 350 nm or less.

16. The electromagnetic shielding composition according to claim 10, wherein the silver particles (A) have an average particle diameter of 30 nm or more and 350 nm or less.

17. The electromagnetic shielding composition according to claim 4, wherein the silver particles (A) have an average particle diameter of 30 nm or more and 350 nm or less.

18. The electromagnetic shielding composition according to claim 11, wherein the silver particles (A) have an average particle diameter of 30 nm or more and 350 nm or less.

19. The electromagnetic shielding composition according to claim 12, wherein the silver particles (A) have an average particle diameter of 30 nm or more and 350 nm or less.

20. The electromagnetic shielding composition according to claim 13, wherein the silver particles (A) have an average particle diameter of 30 nm or more and 350 nm or less.
